(19) United States
(12) Patent Application Publication
(10) Pub. No.: US 2024/0290695 A1
(43) Pub. Date: Aug. 29, 2024

(54) SEMICONDUCTOR DEVICE AND POWER CONVERSION APPARATUS

(71) Applicant: Mitsubishi Electric Corporation, Tokyo (JP)

(72) Inventor: Hiroyuki MASUMOTO, Tokyo (JP)

(73) Assignee: Mitsubishi Electric Corporation, Tokyo (JP)

(21) Appl. No.: 18/405,394

(22) Filed: Jan. 5, 2024

(30) Foreign Application Priority Data
Feb. 27, 2023 (JP) 2023-028190

(51) Int. Cl. H01L 23/495; H01L 23/00; H01L 23/02; H01L 23/31; H01L 23/36

(52) U.S. Cl. CPC H01L 23/49517; H01L 23/02; H01L 23/3121; H01L 23/36; H01L 24/40; H01L 2224/40245; H01L 2924/13055

(57) ABSTRACT

A semiconductor device includes a semiconductor element, an insulating substrate on one surface of which the semiconductor element is mounted, a conductor plates electrically connected to the semiconductor element, a sealing material that seals the insulating substrate, the semiconductor element, and the conductor plates such that the other surface of the insulating substrate and one end portion of the conductor plates are exposed, a control terminal and a main terminal each having one end portion bonded to one end portion of the conductor plates outside the sealing material, and a housing fixed to the other end portion side with respect to the one end portion of the control terminal and the main terminal. In the housing, the control terminal and the main terminal are positioned at predetermined positions.

### BACKGROUND OF THE INVENTION

### Field of the Invention

The present disclosure relates to a semiconductor device and a power conversion apparatus.

### Description of the Background Art

WO 2017/072870 A proposes a power conversion apparatus capable of reducing inductance by bonding an external connection terminal and a terminal of a semiconductor module (corresponding to a semiconductor device) in a case.

In a technique described in WO 2017/072870 A, an insulation distance of components disposed in a case is maintained by filling the case with a sealing material. However, in order to fill the sealing material in the case, not only a flow path of the sealing material and a case shape but also a position and a shape of a terminal in the semiconductor device are structurally restricted. Therefore, it has been difficult to realize a miniaturization of the semiconductor device.

### SUMMARY

An object of the present disclosure is to provide a technique capable of increasing a degree of freedom of a position and a shape of a terminal and realizing a miniaturization of a semiconductor device.

The semiconductor device according to the present disclosure includes a semiconductor element, a substrate, a conductor plate, a sealing material, a terminal, and a housing. The semiconductor element is mounted on one surface of the substrate. The conductor plate is electrically connected to the semiconductor element. The sealing material seals the substrate, the semiconductor element, and the conductor plate such that the other surface of the substrate and one end portion of the conductor plate are exposed. The terminal has one end portion bonded to one end portion of the conductor plate outside the sealing material. The housing is fixed to the other end portion side of the terminal with respect to one end portion of the terminal. In the housing, the terminal is positioned at a predetermined position.

Since the terminal is disposed outside the sealing material, the degree of freedom of the position and the shape of the terminal can be increased, and the semiconductor device can be miniaturized.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a cross-sectional view of a semiconductor device according to a first preferred embodiment;

FIG. 2 is a top view illustrating a connection between a semiconductor element and a conductor plate included in the semiconductor device according to the first preferred embodiment;

FIG. 3 is a cross-sectional view of a semiconductor device according to a second preferred embodiment;

FIG. 4 is a cross-sectional view of a semiconductor device according to a third preferred embodiment;

FIG. 5 is a cross-sectional view of a semiconductor device according to a fourth preferred embodiment;

FIG. 6 is a perspective view for explaining a bonding between a housing and a control terminal and a bonding between a conductor plate and the control terminal included in the semiconductor device according to the fourth preferred embodiment;

FIG. 7 is a cross-sectional view of a semiconductor device according to a fifth preferred embodiment;

FIG. 8 is a cross-sectional view of a semiconductor device according to a sixth preferred embodiment;

FIG. 9 is a cross-sectional view of a semiconductor device according to a seventh preferred embodiment; and

FIG. 10 is a block diagram illustrating a configuration of a power conversion system to which a power conversion apparatus according to an eighth preferred embodiment is applied.

### DESCRIPTION OF THE PREFERRED EMBODIMENTS

### First Preferred Embodiment

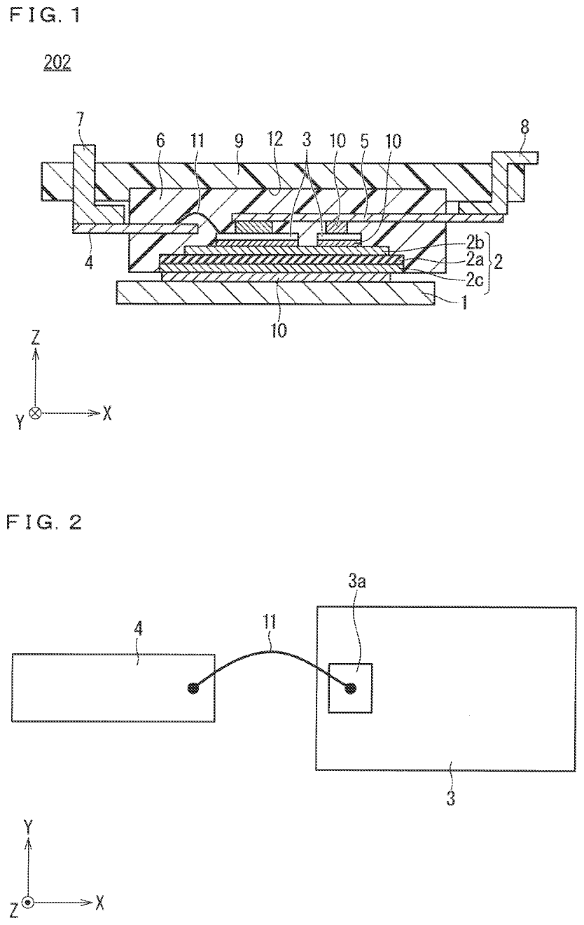

A first preferred embodiment will be described below with reference to the drawings. FIG. 1 is a cross-sectional view of a semiconductor device 202 according to the first preferred embodiment. FIG. 2 is a top view illustrating a connection between a semiconductor element 3 and a conductor plate 4 included in the semiconductor device 202 according to the first preferred embodiment.

In FIG. 1, an X direction, a Y direction, and a Z direction are orthogonal to each other. The X direction, the Y direction, and the Z direction illustrated in the following drawings are also orthogonal to each other. Hereinafter, a direction including the X direction and a −X direction which is a direction opposite to the X direction is also referred to as an “X-axis direction”. In addition, hereinafter, a direction including the Y direction and a −Y direction which is a direction opposite to the Y direction is also referred to as a “Y-axis direction”. In addition, hereinafter, a direction including the Z direction and a −Z direction which is a direction opposite to the Z direction is also referred to as a “Z-axis direction”.

As illustrated in FIG. 1, the semiconductor device includes a cooler 1, an insulating substrate 2 as a substrate, a semiconductor element 3, conductor plates 4 and 5, a sealing material 6, a control terminal 7 and a main terminal 8 as terminals, and a housing 9.

The insulating substrate 2 includes an insulating layer 2a, a circuit pattern 2b, and a conductor foil 2c. The insulating layer 2a is formed of a resin or a ceramic. The circuit pattern 2b is bonded to an upper surface (a surface in the Z direction) of the insulating layer 2a. The conductor foil 2c is bonded to a lower surface (a surface in the −Z direction) of the insulating layer 2a. The circuit pattern 2b and the conductor foil 2c are made of copper having a small conductor resistance.

The semiconductor element 3 is mounted on an upper surface (a surface in the Z direction) of the circuit pattern 2b via a bonding material 10. Although two semiconductor elements 3 are illustrated in FIG. 1, the number of semiconductor elements 3 is not limited to two and may be one or three or more.

The semiconductor element 3 is, for example, an insulated gate bipolar transistor (IGBT) or a metal oxide semiconductor field effect transistor (MOSFET). The semiconductor element 3 may be a reverse conducting IGBT (RC-IGBT). In addition, the semiconductor element 3 is made of silicon (Si) or a wide band gap semiconductor material. The wide band gap semiconductor material is silicon carbide (SiC), gallium nitride (GaN), diamond (C), and the like.

As illustrated in FIGS. 1 and 2, the conductor plate 4 extends in the X-axis direction and is connected to a gate pad 3a of the semiconductor element 3 via wiring 11. The conductor plate 5 extends in the X-axis direction and is bonded to an upper electrode of the semiconductor element 3 by the bonding material 10. The conductor plates 4 and 5 are made of copper. Plating such as Ni or Sn may be formed on the surfaces of the conductor plates 4 and 5. The wiring 11 is formed by wire bonding made of aluminum.

As illustrated in FIG. 1, the sealing material 6 seals the insulating substrate 2, the semiconductor element 3, and the conductor plates 4 and 5 such that a lower surface (a surface in the −Z direction) which is the other surface of the insulating substrate 2, one end portion (an end portion in the −X direction) of the conductor plate 4, and one end portion (an end portion in the X direction) of the conductor plate 5 are exposed. The sealing material 6 is a thermosetting resin such as an epoxy resin.

The housing 9 is formed in a plate shape by a resin such as polyphenylene sulfide (PPS) or a polyethylene terephthalate (PET), and is fixed to an upper surface (a surface in the Z direction) of the sealing material 6 so as to cover the upper surface of the sealing material 6. An end portion of the housing 9 on the sealing material 6 side (the −Z direction), that is, a lower end portion of the housing 9, is provided with a recess 12 to be fitted to an end portion of the sealing material 6 on the housing 9 side (the Z direction), that is, an upper end portion of the sealing material 6. The recess 12 is formed so as to be recessed upward (the Z direction). The housing 9 is fixed to the sealing material 6 by fitting the recess 12 of the housing 9 to the upper end portion of the sealing material 6.

The control terminal 7 is formed in an L shape in a cross-sectional view. In the control terminal 7, one end side extends in the −X direction, and the other end side extends in the Z direction through a bent portion of the L shape. One end portion of the control terminal 7 is bonded to one end portion of the conductor plate 4 outside the sealing material 6. The other end side of one end portion of the control terminal 7 is fixed to the housing 9, and the other end portion of the control terminal 7 protrudes upward (the Z direction) from the housing 9.

The main terminal 8 is formed in a Z shape in a cross-sectional view. In the main terminal 8, one end side extends in the X direction, and the other end side extends in the X direction through two bent portions of the Z shape. One end portion of the main terminal 8 is bonded to one end portion of the conductor plate S outside the sealing material 6. The other end side of the one end portion of the main terminal 8 is fixed to the housing 9, and the other end portion of the main terminal 8 protrudes from the housing 9 in the X direction.

The control terminal 7 and the main terminal 8 are fixed to the housing 9 by being insert-molded in the housing 9. The control terminal 7 and the main terminal 8 are made of copper. Plating such as Ni or Sn may be formed on the surfaces of the control terminal 7 and the main terminal 8.

The conductor plate 4 connected to the control terminal 7 corresponds to a first conductor plate used for controlling the semiconductor element 3. The conductor plate 5 connected to the main terminal 8 corresponds to a second conductor plate used for a purpose other than controlling the semiconductor element 3.

The cooler 1 is bonded to the other surface of the insulating substrate 2, that is, a lower surface (a surface in the −Z direction) of the conductor foil 2c, via the bonding material 10. The cooler 1 is made of a metal such as aluminum or copper. The bonding material 10 for bonding the cooler 1 and the insulating substrate 2, the insulating substrate 2 and the semiconductor element 3, and the semiconductor element 3 and the conductor plate 5 is solder, silver, and the like.

Next, a method of manufacturing the semiconductor device 202 will be briefly described. First, by performing transfer molding using a conventional mold, the insulating substrate 2, the semiconductor element 3, and the conductor plates 4 and 5 are sealed with the sealing material 6. Next, the control terminal 7 and the main terminal 8 are insert-molded in the housing 9 to fix the control terminal 7 and the main terminal 8. Next, after the recess 12 of the housing 9 and the upper end portion of the sealing material 6 are fitted, the conductor plate 4 and the control terminal 7 are bonded, and the conductor plate 5 and the main terminal 8 are bonded. Finally, the insulating substrate 2 and the cooler 1 are bonded.

The bonding between the conductor plate 4 and the control terminal 7 and the bonding between the conductor plate 5 and the main terminal 8 are performed by laser welding or using a soldering iron. By adopting a structure in which this bonding is performed outside the sealing material 6, a degree of freedom of the positions and shapes of the control terminal 7 and the main terminal 8 is improved, and a miniaturization of the semiconductor device 202 can be realized.

Here, in order to realize further miniaturization of the semiconductor device 202, it is important not to seal a periphery of the bonding portion between the conductor plate 4 and the control terminal 7 and a periphery of the bonding portion between the conductor plate 5 and the main terminal 8. This is because, when a case is filled with the sealing material as in a technique described in WO 2017/072870 A, a structural restriction also occurs in the position and shape of the terminals in the semiconductor device, which hinders the miniaturization of the semiconductor device.

In addition, in a case where a flow path of the sealing material cannot be sufficiently secured in the case, air bubbles are generated in the sealing material after molding, a partial electrical discharge occurs inside the air bubbles due to an electric field during driving of the semiconductor device, and an insulation property of the sealing material is impaired by the partial electrical discharge, and a short circuit occurs between different electric potentials, which may lead to operation failure.

In order to solve such a problem, the number of components used in the semiconductor device 202 is large, and the control terminal 7 and the main terminal 8, between which an insulation distance is likely to be difficult to secure, are fixed to the housing 9 in a state of being positioned at predetermined positions, whereby the control terminal 7 and the main terminal 8 are covered with the housing 9, and a positional accuracy of the control terminal 7 and the main terminal 8 is secured. This makes it possible to secure the insulation distance between the control terminal 7 and the main terminal 8.

The housing 9 not only secures the positional accuracy of the control terminal 7 and the main terminal 8 and the insulation distance between the control terminal 7 and the main terminal 8, but also serves to fix the control terminal 7 and the main terminal 8. In a case where a laser is used for bonding the conductor plate 4 and the control terminal 7 and bonding the conductor plate 5 and the main terminal 8, when bonding processing is performed in a state where there is a clearance between the conductor plate 4 and the control terminal 7 and between the conductor plate 5 and the main terminal 8, a bonding quality is impaired. However, since the control terminal 7 and the main terminal 8 are fixed to the housing 9, the clearance can be eliminated between the conductor plate 4 and the control terminal 7 and between the conductor plate 5 and the main terminal 8, and the bonding quality is maintained.

In the first preferred embodiment, one control terminal 7 and one main terminal 8 are fixed to the housing 9, but a plurality of control terminals 7 and a plurality of main terminals 8 may be fixed to the housing 9. Although the control terminal 7 and the main terminal 8 have different shapes in the first preferred embodiment, some of the plurality of control terminals 7 may have different shapes from the remaining control terminals 7. The same applies to the plurality of main terminals 8. In addition, since a large electric current does not flow through the control terminal 7 for controlling the semiconductor element 3, the conductor plate 4 connected to the control terminal 7 may be thinner than the control terminal 7. In addition, a bonding area between the control terminal 7 and the conductor plate 4 may be different from a bonding area between the main terminal 8 and the conductor plate 5, or each of the bonding areas between some control terminals 7 among the plurality of control terminals 7 and the conductor plate 4 may be different from each of the bonding areas between the remaining control terminals 7 and the conductor plate 4. The same applies to the plurality of main terminals 8. These improve the degree of freedom of the positions and shapes of the control terminal 7 and the main terminal 8, and thus contribute to the miniaturization of the semiconductor device 202.

### <Effects>

As described above, in the first preferred embodiment, the semiconductor device 202 includes the semiconductor element 3, the insulating substrate 2 on one surface of which the semiconductor element 3 is mounted, the conductor plates 4 and 5 electrically connected to the semiconductor element 3, the sealing material 6 that seals the insulating substrate 2, the semiconductor element 3, and the conductor plates 4 and 5 such that the other surface of the insulating substrate 2 and one end portion of the conductor plates 4 and 5 are exposed, the control terminal 7 and the main terminal 8 each having one end portion bonded to one end portion of the conductor plates 4 and 5 outside the sealing material 6, and the housing 9 fixed to the other end portion side with respect to the one end portion of the control terminal 7 and the main terminal 8. In the housing 9, the control terminal 7 and the main terminal 8 are positioned at predetermined positions.

Therefore, since the control terminal 7 and the main terminal 8 are disposed outside the sealing material 6, it is possible to increase the degree of freedom of the positions and shapes of the control terminal 7 and the main terminal 8, and it is possible to realize the miniaturization of the semiconductor device 202.

Further, since the positions of the control terminal 7 and the main terminal 8 are fixed by the housing 9, the positional accuracy of the control terminal 7 and the main terminal 8 is enhanced. When the semiconductor device 202 is bonded to the power conversion apparatus, a reliability of the bonding portion is improved.

Further, the semiconductor device 202 includes a plurality of terminals, and the control terminal 7 and the main terminal 8 as the plurality of terminals are fixed to the housing 9 in a state of being separated from each other. Therefore, since a positional relationship between the control terminal 7 and the main terminal 8 is easily determined, the miniaturization of the semiconductor device 202 is easily realized.

Further, each of the bonding portions of the control terminal 7, the main terminal 8, and the conductor plates 4 and 5 are not sealed by the sealing material 6, and are exposed from the sealing material 6. Therefore, the number of components used in the semiconductor device 202 is large, and the insulation distance can be secured between the control terminal 7 and the main terminal 8 where it is difficult to secure the insulation distance. In the semiconductor device 202, the insulation distance using the sealing material is not secured as in the technique described in WO 2017/072870 A, and thus, there is no structural restriction in the position and shape of the terminals in the semiconductor device 202. As a result, the semiconductor device 202 can be miniaturized.

Further, the semiconductor device 202 includes a plurality of conductor plates 4 and 5, and the plurality of conductor plates 4 and 5 include a conductor plate 4 used for controlling the semiconductor element 3 and a conductor plate 5 used for a purpose other than controlling the semiconductor element 3. Therefore, the insulation distance can be secured between the main terminal 8 through which a large electric current flows and the control terminal 7.

The conductor plate 4 is thinner than the control terminal 7 connected to the conductor plate 4. Since the large electric current does not flow through the control terminal 7, it is possible to miniaturize the semiconductor device 202 by reducing the thickness of the conductor plate 4 connected to the control terminal 7.

In addition, the recess 12 to be fitted to the end portion of the sealing material 6 on the housing 9 side is provided at the end portion of the housing 9 on the sealing material 6 side, and the recess 12 of the housing 9 is fitted to the end portion of the sealing material 6 on the housing 9 side, whereby the housing 9 is fixed to the sealing material 6.

Therefore, since a positional accuracy between the sealing material 6 and the control terminal 7 and the main terminal 8 is improved, the semiconductor device 202 can be miniaturized. In addition, since a positional accuracy of the sealing material 6, the conductor plate 4, and the control terminal 7, and a positional accuracy of the sealing material 6, the conductor plate 5, and the main terminal 8 are stabilized, the conductor plate 4 and the control terminal 7, and the conductor plate 5 and the main terminal 8 are easily stably bonded, which leads to improved reliability of the bonding portion.

Since the control terminal 7 and the main terminal 8 are insert-molded in the housing 9, the control terminal 7 and the main terminal 8 are firmly fixed to the housing 9, and the positions of the control terminal 7 and the main terminal 8 are easily determined, so that it is easy to realize the miniaturization of the semiconductor device 202.

In addition, Ni or Sn plating is formed on the surfaces of the control terminal 7 and the main terminal 8. In a case where the control terminal 7 and the main terminal 8 are made of copper, the surfaces are oxidized if there is no plating on the surfaces. Therefore, adhesion at the bonding portion between the conductor plate 4 and the control terminal 7 and the bonding portion between the conductor plate 5 and the main terminal 8 is weakened, and a large bonding area is required. Since the bonding quality can be maintained without securing a large area by plating, an effect of miniaturizing the semiconductor device 202 can be easily obtained.

In addition, the semiconductor device 202 includes the plurality of terminals 7 and 8, and some of the plurality of terminals 7 and 8 are different in shape from the remaining terminals. In addition, some of the plurality of terminals 7 and 8 have different thicknesses from the remaining terminals. Therefore, since the degree of freedom of the shapes of the control terminal 7 and the main terminal 8 is increased, it is easy to realize the miniaturization of the semiconductor device 202.

In addition, the semiconductor device 202 includes the plurality of terminals 7 and 8, and each of the bonding areas between some of the plurality of terminals 7 and 8 and the conductor plates 4 and 5 is different from each of the bonding areas between the remaining terminals and the conductor plates 4 and 5.

Therefore, it is easy to realize the miniaturization of the semiconductor device 202 by achieving both adhesion and a bonding area of an appropriate size for terminals of a plurality of shapes. In addition, when the conductor plate 4 and the control terminal 7, and the conductor plate 5 and the main terminal 8 are bonded to each other, a bonding processing condition suitable for the shapes of the control terminal 7 and the main terminal 8 is set, so that the reliability of the bonding portion can also be secured.

In addition, since the control terminal 7 and the conductor plate 4, and the main terminal 8 and the conductor plate 5 are bonded by laser welding, unlike a case of screw fastening, an additional component is unnecessary, and thus it is easy to realize the miniaturization of the semiconductor device 202. In particular, a height of the semiconductor device 202 is reduced.

In addition, since the semiconductor element 3 is a reverse conducting IGBT, the number of semiconductor elements 3 can be reduced, so that the semiconductor device 202 can be further miniaturized.

In addition, since the semiconductor material of the semiconductor element 3 is SiC, the miniaturization and a densification of the semiconductor device 202 can be realized by using a low-loss SiC.

### Second Preferred Embodiment

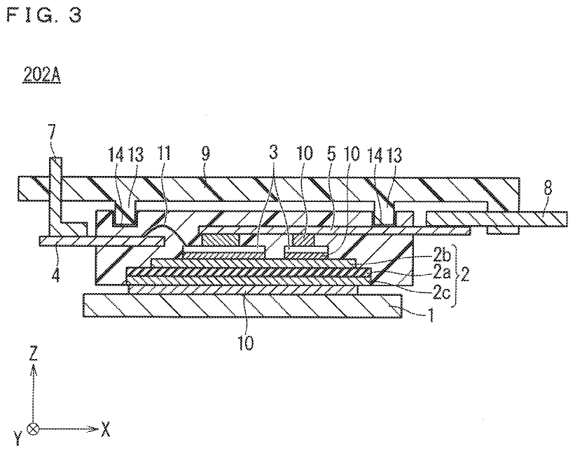

Next, a semiconductor device 202A according to a second preferred embodiment will be described. FIG. 3 is a cross-sectional view of the semiconductor device 202A according to the second preferred embodiment. In the second preferred embodiment, the same components as those described in the first preferred embodiment are denoted by the same reference numerals, and description thereof is omitted.

As illustrated in FIG. 3, in the second preferred embodiment, a recess 14 recessed downward (the −Z direction) is provided at the end portion of the sealing material 6 on the housing 9 side, that is, an upper end portion (an end portion in the Z direction) of the sealing material 6. Further, at an end portion of the housing 9 on the sealing material 6 side, that is, at a lower end portion (an end portion in the −Z direction) of the housing 9, a protrusion 13 protruding downward (the −Z direction) is provided instead of the recess 12. The housing 9 is fixed to the sealing material 6 by fitting the protrusion 13 of the housing 9 into the recess 14 of the sealing material 6.

The end portion of the housing 9 in the X direction is bent downward (the −Z direction). The main terminal 8 is formed in a flat plate shape and extends in the X-axis direction. One end portion of the main terminal 8 is bonded to one end portion of the conductor plate 5 outside the sealing material 6. The other end side with respect to the one end portion of the main terminal 8 is fixed to the housing 9, and the other end portion of the main terminal 8 protrudes from the housing 9 in the X direction.

### <Effects>

As described above, in the second preferred embodiment, the recess 14 is provided at the end portion of the sealing material 6 on the housing 9 side, the protrusion 13 fitted to the recess 14 is provided at the end portion of the housing 9 on the side of the sealing material 6, and the protrusion 13 of the housing 9 is fitted to the recess 14 of the sealing material 6, whereby the housing 9 is fixed to the sealing material 6.

Therefore, since the housing 9 for fixing the control terminal 7 and the main terminal 8 is easily positioned by the sealing material 6, the positional accuracy of the control terminal 7 and the main terminal 8 is enhanced, and the miniaturization of the semiconductor device 202 is easily realized.

### Third Preferred Embodiment

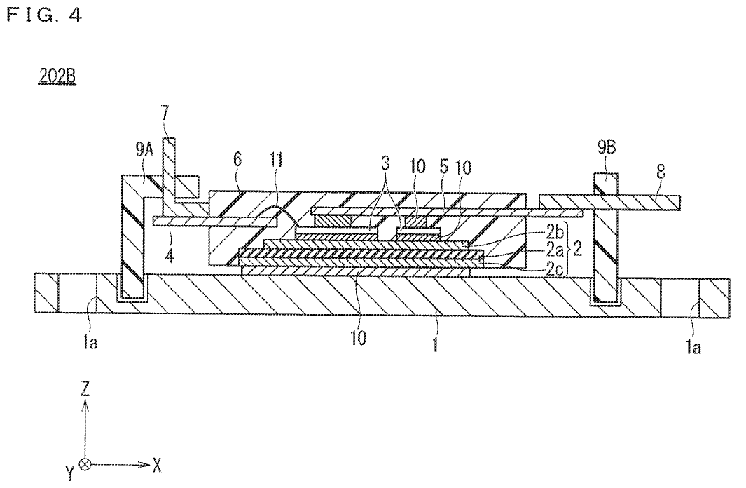

Next, a semiconductor device 202B according to a third preferred embodiment will be described. FIG. 4 is a cross-sectional view of the semiconductor device 202B according to the third preferred embodiment. In the third preferred embodiment, the same components as those described in the first and second preferred embodiments are denoted by the same reference numerals, and description thereof is omitted.

As illustrated in FIG. 4, in the third preferred embodiment, housings 9A and 9B are provided instead of the housing 9 in the second preferred embodiment. The housing 9A has a vertical portion extending in the Z direction and a horizontal portion extending in the X direction, and is formed in an L shape in a cross-sectional view. The housing 9A is disposed so as to cover a side surface of the sealing material 6 in the −X direction. The housing 9B extends in the Z direction and is disposed so as to cover the side surface of the sealing material 6 in the X direction. Although not illustrated, the housing 9A and the housing 9B may be integrally formed as one housing so as to cover the upper surface (the surface in the Z direction) of the sealing material 6 in addition to the side surface of the sealing material 6 in the X-axis direction.

The cooler 1 is formed to have a main surface larger than a region surrounded by the housings 9A and 9B when viewed from the Z direction so that the housings 9A and 9B can be fixed. Lower end portions of the housings 9A and 9B are fixed to the cooler 1 by fitting or bonding. In addition, screw holes 1a for fixing the cooler 1 to the power conversion apparatus are provided at positions outside the housing 9A (the −X direction) and outside the housing 9B (the X direction) in the cooler 1.

### <Effects>

As described above, in the third preferred embodiment, the semiconductor device 202B further includes the cooler 1 bonded to the other surface of the insulating substrate 2, and the housings 9A and 9B and the cooler 1 are fixed by fitting or bonding. Therefore, since the housing 9A for fixing the control terminal 7 and the housing 9B for fixing the main terminal 8 are positioned by the cooler 1, the positional accuracy of the control terminal 7 and the main terminal 8 is enhanced, and the semiconductor device 202 can be easily miniaturized.

### Fourth Preferred Embodiment

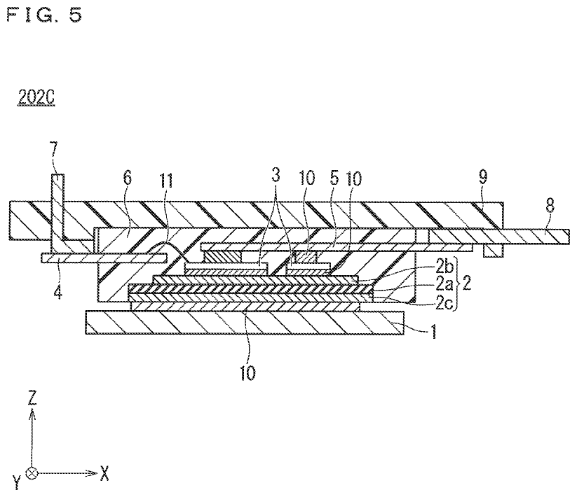

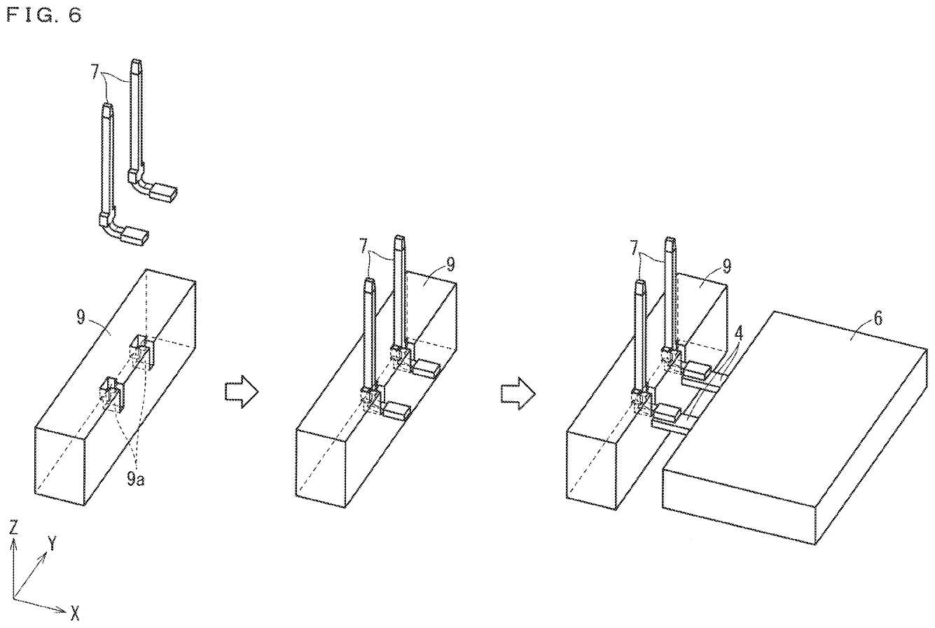

Next, a semiconductor device 202C according to a fourth preferred embodiment will be described. FIG. 5 is a cross-sectional view of the semiconductor device 202C according to the fourth preferred embodiment. FIG. 6 is a perspective view for explaining a connection between the housing 9 and the control terminal 7 and a bonding between the conductor plate 4 and the control terminal 7 included in the semiconductor device 202C according to the fourth preferred embodiment. In the fourth preferred embodiment, the same components as those described in the first to third preferred embodiments are denoted by the same reference numerals, and description thereof is omitted.

As illustrated in FIGS. 5 and 6, in the fourth preferred embodiment, as compared with the second preferred embodiment, the protrusion 13 and the recess 14 are not provided, and the control terminal 7 and the main terminal 8 are outsert-molded in the housing 9, the control terminal 7 is bonded to the conductor plate 4, and the main terminal 8 is bonded to the conductor plate 5, whereby the housing 9 and the sealing material 6 are fixed.

Specifically, as illustrated in FIG. 6, the other end portion side of the control terminal 7 extends in a direction (a Z-axis direction) perpendicular to the bonding surface between the one end portion of the control terminal 7 and the conductor plate 4. A fitting groove 9a into which the bent portion of the control terminal 7 is fitted is formed at an end portion in the −X direction of the housing 9, and the control terminal 7 is fixed to the housing 9 by fitting the control terminal 7 into the fitting groove 9a. Although not illustrated, a fitting groove in which the other end portion side is fitted with respect to one end portion of the main terminal 8 is formed at an end portion in the X direction of the housing 9, and the main terminal 8 is fixed to the housing 9 by fitting the main terminal 8 into the fitting groove. The control terminals 7 and 7A and the main terminals 8 and 8A of other preferred embodiments may also be outsert-molded in the housing 9.

### <Effects>

As described above, in the fourth preferred embodiment, the other end portion side of the control terminal 7 extends in the direction perpendicular to the bonding surface between the one end portion of the control terminal 7 and the conductor plate 4, and the control terminal 7 is outsert-molded in the housing 9.

Therefore, it is possible to eliminate a gap between the control terminal 7 and the conductor plate 4 in the Z-axis direction during the bonding processing between the control terminal 7 and the conductor plate 4 while maintaining a positional degree of freedom of the control terminal 7 in the Z-axis direction. Therefore, the reliability of the bonding portion between the control terminal 7 and the conductor plate 4 is improved. In general, since the control terminal 7 electrically connected from a control unit of the semiconductor element 3 via the wiring 11 and the conductor plate 4 is required to have a positional accuracy in the X-axis direction and the Y-axis direction rather than accuracy in the Z-axis direction, it is possible to achieve both reliability and positional accuracy in the control terminal 7.

The control terminal 7 has an L shape, the housing 9 is provided with the fitting groove 9a into which the bent portion of the control terminal 7 is fitted, and the bent portion of the control terminal 7 is fitted into the fitting groove 9a of the housing 9, whereby the control terminal 7 is fixed to the housing 9.

Therefore, the positional accuracy of the control terminal 7 in the X-axis direction and the Y-axis direction is improved, which leads to the miniaturization of the semiconductor device 202C.

### Fifth Preferred Embodiment

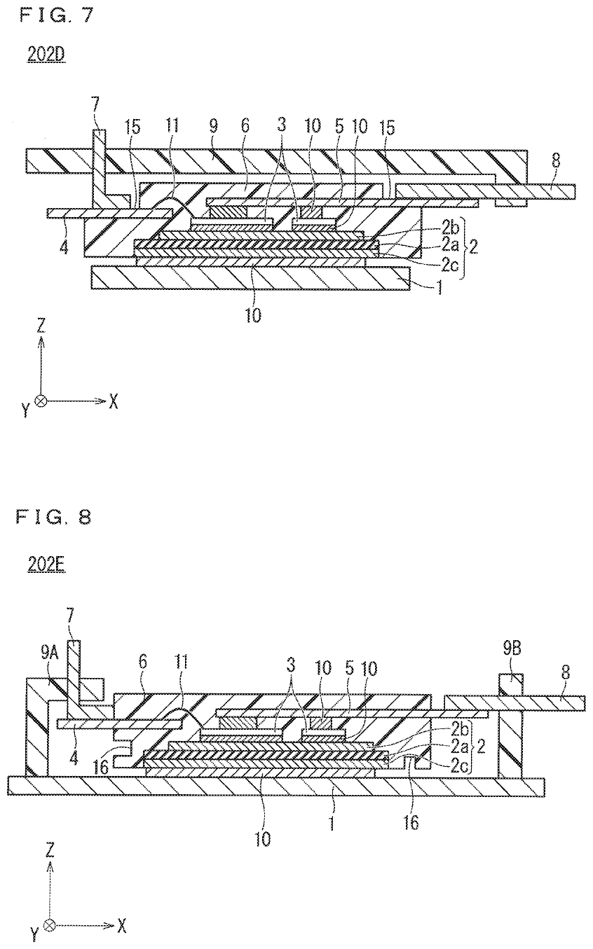

Next, a semiconductor device 202D according to a fifth preferred embodiment will be described. FIG. 7 is a cross-sectional view of the semiconductor device 202D according to the fifth preferred embodiment. In the fifth preferred embodiment, the same components as those described in the first to fourth preferred embodiments are denoted by the same reference numerals, and description thereof is omitted.

As illustrated in FIG. 7, in the fifth preferred embodiment, as compared with the fourth preferred embodiment, two notches 15 are provided at the end portion of the sealing material 6 on the housing 9 side, that is, the upper portion (the portion in the Z direction) of the sealing material 6. The two notches 15 are provided at the end portion in the −X direction and the end portion in the X direction of the sealing material 6. One end portion of the control terminal 7 is located in one notch 15, and one end portion of the main terminal 8 is located in the other notch 15. The notches 15 may also be provided in the sealing material 6 of another preferred embodiment.

### <Effects>

As described above, in the fifth preferred embodiment, the notches 15 are provided at the end portion of the sealing material 6 on the housing 9 side, and one end portion of each of the control terminal 7 and the main terminal 8 is located in the notches 15.

Therefore, the control terminal 7 and the main terminal 8 can be disposed inside an outer periphery of a rectangular parallelepiped shape of the sealing material 6, which leads to the miniaturization of the semiconductor device 202D. In addition, the insulation distance between the cooler 1 and the control terminal 7 and the main terminal 8 is easily secured, which leads to further miniaturization of the semiconductor device 202D.

### Sixth Preferred Embodiment

Next, a semiconductor device 202E according to a sixth preferred embodiment will be described. FIG. 8 is a cross-sectional view of the semiconductor device 202E according to the sixth preferred embodiment. In the sixth preferred embodiment, the same components as those described in the first to fifth preferred embodiments are denoted by the same reference numerals, and description thereof is omitted.

As illustrated in FIG. 8, in the sixth preferred embodiment, as compared with the third preferred embodiment, grooves 16 are provided in a portion between the conductor plates 4 and 5 and the cooler 1 in the sealing material 6. Specifically, one groove 16 is provided in a side portion of the sealing material 6 between the conductor plate 4 and the cooler 1, and one groove 16 is provided in a bottom portion of the sealing material 6 between the conductor plate 5 and the cooler 1. These two grooves 16 are provided to secure an insulation distance between the conductor plates 4 and 5 and the cooler 1. Note that a groove 16 may also be provided in the sealing material 6 of another preferred embodiment. Further, as in the case of FIG. 4, the housing 9A and the housing 9B may be integrally formed as one housing so as to cover the upper surface (the surface in the Z direction) of the sealing material 6 in addition to the side surface of the sealing material 6 in the X-axis direction.

### <Effects>

As described above, in the sixth preferred embodiment, the grooves 16 are provided in the portion between the conductor plates 4 and 5 and the cooler 1 in the sealing material 6. When a rated voltage of the semiconductor device 202E is high, the insulation distance between the conductor plates 4 and 5 and the cooler 1 is required, but in the sixth preferred embodiment, the insulation distance between the conductor plates 4 and 5 and the cooler 1 can be secured. As a result, an electrical discharge can be suppressed without increasing a size of the semiconductor device 202E.

### Seventh Preferred Embodiment

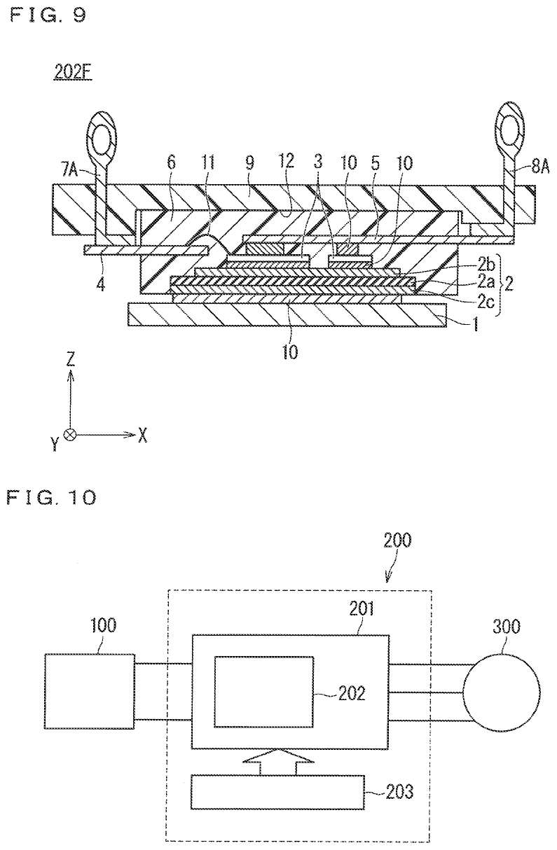

Next, a semiconductor device 202F according to a seventh preferred embodiment will be described. FIG. 9 is a cross-sectional view of the semiconductor device 202F according to the seventh preferred embodiment. In the seventh preferred embodiment, the same components as those described in the first to sixth preferred embodiments are denoted by the same reference numerals, and description thereof is omitted.

As illustrated in FIG. 9, in the seventh preferred embodiment, as compared with the first preferred embodiment, a control terminal 7A and a main terminal 7B having a press-fit shape are provided instead of the control terminal 7 and the main terminal 8. Note that a terminal having no press-fit shape may be adopted for one of the control terminal 7A and the main terminal 7B. Instead of the control terminal 7 and the main terminal 8 of the second to sixth preferred embodiments, the control terminal 7A and the main terminal 7B having the press-fit shape may be adopted.

### <Effects>

As described above, in the seventh preferred embodiment, since the control terminal 7 and the main terminal 8 have the press-fit shape, when the semiconductor device 202F is incorporated in the power conversion apparatus, an electrical connection between the control terminal 7A and the main terminal 7B is facilitated, so that an assemblability of the power conversion apparatus is improved. This leads to a miniaturization of the power conversion apparatus.

### Eighth Preferred Embodiment

In the present preferred embodiment, the semiconductor device according to the above-described first to seventh preferred embodiments is applied to a power conversion apparatus. Application of the semiconductor device according to the first to seventh preferred embodiments is not limited to a specific power conversion apparatus, but a case where the semiconductor device according to the first to seventh preferred embodiments is applied to a three-phase inverter will be described below as the eighth preferred embodiment.

FIG. 10 is a block diagram illustrating a configuration of a power conversion system to which the power conversion apparatus according to the eighth preferred embodiment is applied.

The power conversion system illustrated in FIG. 10 includes a power supply 100, a power conversion apparatus 200, and a load 300. The power supply 100 is a DC power supply, and supplies DC power to the power conversion apparatus 200. The power supply 100 can include various components, and can include, for example, a DC system, a solar cell, and a storage battery, or may include a rectifier circuit or an AC/DC converter connected to an AC system. In addition, the power supply 100 may include a DC/DC converter that converts a DC power output from the DC system into a predetermined power output.

The power conversion apparatus 200 is a three-phase inverter connected between the power supply 100 and the load 300, converts DC power supplied from the power supply 100 into AC power, and supplies the AC power to the load 300. As illustrated in FIG. 10, the power conversion apparatus 200 includes a main conversion circuit 201 that converts DC power into AC power and outputs the AC power, and a control circuit 203 that outputs a control signal for controlling the main conversion circuit 201 to the main conversion circuit 201.

The load 300 is a three-phase electric motor driven by the AC power supplied from the power conversion apparatus 200. The load 300 is not limited to a specific application, but is an electric motor mounted on various electric devices, and is used as, for example, an electric motor for a hybrid vehicle, an electric vehicle, a railway vehicle, an elevator, or an air conditioner.

Hereinafter, details of the power conversion apparatus 200 will be described. The main conversion circuit 201 includes a switching element (not illustrated) and a freewheeling diode (not illustrated), converts DC power supplied from the power supply 100 into AC power by switching of the switching element, and supplies the AC power to the load 300. Although there are various specific circuit configurations of the main conversion circuit 201, the main conversion circuit 201 according to the present preferred embodiment is a two-level three-phase full bridge circuit, and can include six switching elements and six freewheeling diodes antiparallel to the respective switching elements.

At least one of each switching element and each freewheeling diode of the main conversion circuit 201 is configured by a semiconductor device corresponding to any one of the above-described first to seventh preferred embodiments. In the eighth preferred embodiment, as an example, the main conversion circuit 201 includes the semiconductor device 202 according to the first preferred embodiment. The six switching elements are connected in series for every two switching elements to constitute upper and lower arms, and each of the upper and lower arms constitutes each phase (U-phase, V-phase, W-phase) of the full bridge circuit. Output terminals of the upper and lower arms, that is, the three output terminals of the main conversion circuit 201, are connected to the load 300.

Further, the main conversion circuit 201 includes a drive circuit (not illustrated) that drives each switching element, but the drive circuit may be built into the semiconductor device 202, or may include a drive circuit separate from the semiconductor device 202. The drive circuit generates a drive signal for driving the switching elements of the main conversion circuit 201, and supplies the drive signal to a control electrode of the switching elements of the main conversion circuit 201. Specifically, in accordance with the control signal from the control circuit 203 to be described later, a drive signal for turning on the switching element and a drive signal for turning off the switching element are output to the control electrode of each switching element. When the switching element is maintained in the ON state, the drive signal is a voltage signal (ON signal) equal to or higher than a threshold voltage of the switching element, and when the switching element is maintained in the OFF state, the drive signal is a voltage signal (OFF signal) equal to or lower than the threshold voltage of the switching element.

The control circuit 203 controls the switching elements of the main conversion circuit 201 so that a desired power is supplied to the load 300. Specifically, a time (ON time) during which each switching element of the main conversion circuit 201 is to be turned on is calculated based on the power to be supplied to the load 300. For example, the main conversion circuit 201 can be controlled by pulse-width modulation (PWM) control that modulates the ON time of the switching element according to the voltage to be output. Then, a control command (control signal) is output to the drive circuit included in the main conversion circuit 201 such that the ON signal is output to the switching element to be turned on at each time point, and the OFF signal is output to the switching element to be turned off at each time point. The drive circuit outputs the ON signal or the OFF signal as the drive signal to the control electrode of each switching element according to the control signal.

In the power conversion apparatus according to the present preferred embodiment, since the semiconductor device 202 is applied as the switching element and the freewheeling diode of the main conversion circuit 201, miniaturization can be realized.

In the present preferred embodiment, the example in which the semiconductor device according to the first to seventh preferred embodiments is applied to a two-level three-phase inverter has been described, but the application of the semiconductor device according to the first to seventh preferred embodiments is not limited thereto, and can be applied to various power conversion apparatuses. In the present preferred embodiment, a two-level power conversion apparatus is used, but a three-level or multi-level power conversion apparatus may be used. In a case where power is supplied to a single-phase load, the semiconductor device according to the first to seventh preferred embodiments may be applied to a single-phase inverter. When power is supplied to a DC load or the like, the semiconductor device according to the first to seventh preferred embodiments can be applied to a DC/DC converter or an AC/DC converter.

In addition, the power conversion apparatus to which the semiconductor device according to first to seventh preferred embodiments is applied is not limited to the case where the above-described load is an electric motor, and can also be used as, for example, a power supply apparatus of an electrical discharge machine, a laser beam machine, an induction heating cooker, or a non-contact power supply system, and can also be used as a power conditioner of a solar power generation system, a power storage system, and the like.

Note that the preferred embodiments can be freely combined, and the preferred embodiments can be appropriately modified or omitted.

Hereinafter, various aspects of the present disclosure will be collectively described as appendices.

### (Appendix 1)

A semiconductor device comprising:
a semiconductor element;
a substrate having one surface on which the semiconductor element is mounted;
a conductor plate electrically connected to the semiconductor element;
a sealing material that seals the substrate, the semiconductor element, and the conductor plate such that the other surface of the substrate and one end portion of the conductor plate are exposed;
a terminal having one end portion bonded to the one end portion of the conductor plate outside the sealing material; and
a housing fixed to the other end portion side of the terminal with respect to the one end portion of the terminal,
wherein the terminal is positioned at a predetermined position in the housing.

### (Appendix 2)

The semiconductor device according to Appendix 1 comprising a plurality of the terminals,
wherein the plurality of terminals are fixed to the housing in a state of being separated from each other.

### (Appendix 3)

The semiconductor device according to Appendix 1 or 2, wherein a bonding portion between the terminal and the conductor plate is not sealed by the sealing material and is exposed from the sealing material.

### (Appendix 4)

The semiconductor device according to any one of Appendices 1 to 3 comprising a plurality of the conductor plates,
wherein the plurality of conductor plates includes a first conductor plate used for controlling the semiconductor element and a second conductor plate used for a purpose other than controlling the semiconductor element.

### (Appendix 5)

The semiconductor device according to Appendix 4, wherein the first conductor plate is thinner than the terminal connected to the first conductor plate.

### (Appendix 6)

The semiconductor device according to any one of Appendices 1 to 5, wherein
a recess to be fitted with an end portion of the sealing material on the housing side is provided at an end portion of the housing on the sealing material side, and
the housing is fixed to the sealing material by fitting the recess of the housing into the end portion of the sealing material on the housing side.

### (Appendix 7)

The semiconductor device according to any one of Appendices 1 to 5, wherein
a recess is provided at an end portion of the sealing material on the housing side,
a protrusion fitted into the recess is provided at an end portion of the housing on the sealing material side, and
the housing is fixed to the sealing material by fitting the protrusion of the housing into the recess of the sealing material.

### (Appendix 8)

The semiconductor device according to any one of Appendices 1 to 7 further comprising a cooler bonded to the other surface of the substrate,
wherein the housing and the cooler are fixed by fitting or bonding.

### (Appendix 9)

The semiconductor device according to any one of Appendices 1 to 8, wherein
the other end portion side of the terminal extends in a direction perpendicular to a bonding surface between the one end portion of the terminal and the conductor plate, and
the terminal is outsert-molded in the housing.

### (Appendix 10)

The semiconductor device according to Appendix 9, wherein
the terminal has an L shape,
the housing is provided with a fitting groove into which a bent portion of the terminal is fitted, and
the terminal is fixed to the housing by fitting the bent portion of the terminal into the fitting groove of the housing.

### (Appendix 11)

The semiconductor device according to any one of Appendices 1 to 8, wherein the terminal is insert-molded in the housing.

### (Appendix 12)

The semiconductor device according to any one of Appendices 1 to 11, wherein
a notch is provided at the end portion of the sealing material on the housing side, and
the one end portion of the terminal is located in the notch.

### (Appendix 13)

The semiconductor device according to Appendix 8, wherein a groove is provided in a portion between the conductor plate and the cooler in the sealing material.

### (Appendix 14)

The semiconductor device according to any one of Appendices 1 to 13, wherein the terminal has a press-fit shape.

### (Appendix 15)

The semiconductor device according to any one of Appendices 1 to 14, wherein
Ni or Sn plating is formed on a surface of the terminal.

### (Appendix 16)

The semiconductor device according to any one of Appendices 1 to 15 comprising a plurality of the terminals,
wherein some of the plurality of terminals are different in shape from the remaining terminals.

### (Appendix 17)

The semiconductor device according to any one of Appendices 1 to 16 comprising a plurality of the terminals,
wherein some of the plurality of terminals have different thicknesses from the remaining terminals.

### (Appendix 18)

The semiconductor device according to any one of Appendices 1 to 17 comprising a plurality of the terminals,
wherein each of the bonding areas of some of the plurality of terminals and the conductor plate is different from each of the bonding areas of the remaining terminals and the conductor plate.

### (Appendix 19)

The semiconductor device according to any one of Appendices 1 to 18, wherein the terminal and the conductor plate are bonded by laser welding.

### (Appendix 20)

The semiconductor device according to any one of Appendices 1 to 19, wherein the semiconductor element is a reverse conducting IGBT.

### (Appendix 21)

The semiconductor device according to any one of Appendices 1 to 20, wherein a semiconductor material of the semiconductor element is SiC.

### (Appendix 22)

A power conversion apparatus comprising:
a main conversion circuit that includes the semiconductor device according to any one of Appendices 1 to 21 and converts and outputs input power; and
a control circuit that outputs a control signal for controlling the main conversion circuit to the main conversion circuit.

While the disclosure has been shown and described in detail, the foregoing description is in all aspects illustrative and not restrictive. It is therefore understood that numerous modifications and variations can be devised.

What is claimed is:

1. A semiconductor device comprising:
a semiconductor element;
a substrate having one surface on which the semiconductor element is mounted;
a conductor plate electrically connected to the semiconductor element;
a sealing material that seals the substrate, the semiconductor element, and the conductor plate such that the other surface of the substrate and one end portion of the conductor plate is exposed;
a terminal having one end portion bonded to the one end portion of the conductor plate outside the sealing material; and
a housing fixed to the other end portion side of the terminal with respect to the one end portion of the terminal,
wherein the terminal is positioned at a predetermined position in the housing.

2. The semiconductor device according to claim 1 comprising a plurality of the terminals,
wherein the plurality of terminals are fixed to the housing in a state of being separated from each other.

3. The semiconductor device according to claim 1, wherein a bonding portion between the terminal and the conductor plate is not sealed by the sealing material and is exposed from the sealing material.

4. The semiconductor device according to claim 1 comprising a plurality of the conductor plates,
wherein the plurality of conductor plates includes a first conductor plate used for controlling the semiconductor element and a second conductor plate used for a purpose other than controlling the semiconductor element.

5. The semiconductor device according to claim 4, wherein the first conductor plate is thinner than the terminal connected to the first conductor plate.

6. The semiconductor device according to claim 1, wherein
a recess to be fitted with an end portion of the sealing material on the housing side is provided at an end portion of the housing on the sealing material side, and
the housing is fixed to the sealing material by fitting the recess of the housing into the end portion of the sealing material on the housing side.

7. The semiconductor device according to claim 1, wherein
a recess is provided at an end portion of the sealing material on the housing side,
a protrusion fitted into the recess is provided at an end portion of the housing on the sealing material side, and
the housing is fixed to the sealing material by fitting the protrusion of the housing into the recess of the sealing material.

8. The semiconductor device according to claim 1 further comprising a cooler bonded to the other surface of the substrate,
wherein the housing and the cooler are fixed by fitting or bonding.

9. The semiconductor device according to claim 1, wherein
the other end portion side of the terminal extends in a direction perpendicular to a bonding surface between the one end portion of the terminal and the conductor plate, and
the terminal is outsert-molded in the housing.

10. The semiconductor device according to claim 9, wherein
the terminal has an L shape,
the housing is provided with a fitting groove into which a bent portion of the terminal is fitted, and
the terminal is fixed to the housing by fitting the bent portion of the terminal into the fitting groove of the housing.

11. The semiconductor device according to claim 1, wherein the terminal is insert-molded in the housing.

12. The semiconductor device according to claim 1, wherein
a notch is provided at the end portion of the sealing material on the housing side, and
the one end portion of the terminal is located in the notch.

13. The semiconductor device according to claim 8, wherein a groove is provided in a portion between the conductor plate and the cooler in the sealing material.

14. The semiconductor device according to claim 1, wherein the terminal has a press-fit shape.

15. The semiconductor device according to claim 1, wherein Ni or Sn plating is formed on a surface of the terminal.

16. The semiconductor device according to claim 1 comprising a plurality of the terminals,
wherein some of the plurality of terminals are different in shape from the remaining terminals.

17. The semiconductor device according to claim 1 comprising a plurality of the terminals,
wherein some of the plurality of terminals have different thicknesses from the remaining terminals.

18. The semiconductor device according to claim 1 comprising a plurality of the terminals,
wherein each of the bonding areas of some of the plurality of terminals and the conductor plate is different from each of the bonding areas of the remaining terminals and the conductor plate.

19. The semiconductor device according to claim 1, wherein the terminal and the conductor plate are bonded by laser welding.

20. The semiconductor device according to claim 1, wherein the semiconductor element is a reverse conducting IGBT.

21. The semiconductor device according to claim 1, wherein a semiconductor material of the semiconductor element is SiC.

22. A power conversion apparatus comprising:
a main conversion circuit that includes the semiconductor device according to claim 1 and converts and outputs input power, and
a control circuit that outputs a control signal for controlling the main conversion circuit to the main conversion circuit.
